(19) United States
(12) Patent Application Publication
(10) Pub. No.: US 2026/0194572 A1
(43) Pub. Date: Jul. 9, 2026

(54) PROBE, TEST HEAD INCLUDING THE SAME, AND METHOD FOR MANUFACTURING THE TEST HEAD

(71) Applicant: Lomites Co., Ltd., Zhubei City (CN)

(72) Inventor: Yung-Sheng KUNG, Zhubei City (TW)

(21) Appl. No.: 19/441,949

(22) Filed: Jan. 7, 2026

(30) Foreign Application Priority Data
Jan. 8, 2025 (CN) 202510030140.1
Sep. 12, 2025 (CN) 202511306811.9

(51) Int. Cl. G01R 31/28; G01R 1/067; G01R 3/00

(52) U.S. Cl. CPC G01R 31/2886; G01R 1/067; G01R 3/00

(57) ABSTRACT

A probe, a test head including the same, and a method for manufacturing the test head are disclosed. The test head comprises the probe. The probe comprises a plurality of metal strips horizontally stacked and welded together, wherein each of the plurality of metal strips extends longitudinally in an up-down direction. At least one of the metal strips is provided with a flattened portion formed by a forging process, the flattened portion being recessed in the stacking direction to define a gap. The metal strips are welded together at their upper ends, at their lower ends, or at both ends to jointly form a contact surface configured to engage with a contact element in the up-down direction. The process thereof is simplified, thereby reducing the manufacturing cost of the probe.

### BACKGROUND OF THE INVENTION

### 1. Field of the Invention

The present invention relates to a probe and a test head including the probe, and more particularly, to a probe that is easy to manufacture and comprises a multi-layer structure, and a test head including the probe, and a method for manufacturing the test head.

### 2. Description of the Related Art

A test head is utilized for the electrical testing of circuits integrated on a chip before the circuits are assembled into a chip package. A typical test head generally includes at least two guide plates spaced apart by a partition plate, and a plurality of probes extending through the guide plates. The guide plates are provided with a plurality of through-holes for receiving the respective probes. The probe is bent within the partition plate and slides axially in the through-hole during press contact. The upper end of the probe contacts the contact pad of a space transformer, and the lower end contacts the contact pad of the device under test (DUT).

Currently, most probes on the market are primarily Microelectromechanical System (MEMS) probes or monolithic probes manufactured by a laser cutting process. MEMS refers to forming a probe by depositing layers and etching away superfluous material. Its manufacturing process is highly complex, and probes manufactured by MEMS processes require specific raw materials, generally special metals. Therefore, MEMS probes are very expensive due to both the complicated process flow and the high cost of raw materials. Manufacturing a monolithic probe using a laser cutting method involves cutting multiple probes from a single metal sheet. This method requires numerous processes, such as adhering the material to a piece of adhesive before cutting and then removing the adhesive after cutting. This process generates substantial waste, leading to a significant waste of raw materials. Furthermore, the metal sheets used for making probes mostly made of silver or copper, which are more expensive than ordinary metals used for making conductive terminals. Consequently, the high manufacturing cost of laser-cut probes is exacerbated by the extensive waste of expensive raw materials. On one hand, the complex process and high cost of MEMS probe manufacturing, coupled with the intricate pre-and post-processing steps (adhering and removal of adhesive) and considerable material waste associated with laser cutting, significantly increase the manufacturing cost. As probes are consumables requiring frequent replacement, and their materials (such as silver or copper) are inherently expensive, the material waste from laser cutting substantially raises the production cost of the probe. On the other hand, since the test head is a reusable product intended for repeated circuit testing, long-term use causes a certain degree of wear on the probe. A portion of the probe's length at both ends needs to be worn down to continue use and extend the lifespan of the test head. This leads to the probe's overall length gradually shortening, and the probe's stiffness slowly increasing. An increased stiffness means that the force applied by the probe to the DUT is greater, which raises the risk of scratching the DUT and damaging the probe itself upon contact.

To address the problem of excessive stress, the traditional approach involves forming a hole in the middle of the probe body. This increases the probe's flexibility and reduces the force exerted by the probe's contact tip on the pad when it engages with a device under test DUT. However, due to the probe's extremely small diameter (even finer than a human hair), the hole-making process imposes exceptionally stringent precision requirements. Standard laser equipment lacks the necessary accuracy for this task. Consequently, the industry predominantly employs high-end laser systems to cut these apertures in the probe. The high cost of such advanced laser equipment renders this laser-cutting method relatively expensive. On the other hand, since laser cutting utilizes the high-energy density at the focus of the laser beam to melt and vaporize the metal material, heat diffuses during processing to form a heat-affected zone around the focus. Consequently, the actual aperture cut is larger than the actual spot size. For example, if the selected spot size is 0.005 mm, the probe material around the focal spot will melt due to the thermal effect, resulting in a final aperture size potentially between 0.008 mm and 0.009 mm. Thus, the laser cutting method for creating apertures lacks flexibility in adjusting the size, making it difficult to cut the precise dimensions desired by the user.

Therefore, there is a need to design a new probe, a test head including the probe, and a method for manufacturing the test head to overcome the aforementioned problems.

### SUMMARY OF THE INVENTION

An objective of the present invention is to provide a new probe, a test head including the probe, and a method for manufacturing the test head to overcome the aforementioned problems of the prior art and to reduce the manufacturing cost of the probe.

To achieve the above object, the present invention provides a probe, comprising a plurality of metal strips stacked and welded together along a horizontal direction, wherein each metal strip extends longitudinally along an up-down direction, and wherein at least one of the metal strips comprises at least one flattened portion that is formed by forging and recessed in a stacking direction, such that a gap is formed between the flattened portion and an adjacent metal strip, wherein upper ends, lower ends, or both ends of the metal strips are welded together, and wherein, during testing, the lower end of at least one of the metal strips engages with a device under test (DUT) downwardly, and the upper end of at least one of the metal strips engages with a contact element upwardly.

Further, the metal strip is a cylindrical metal wire prior to the forging, and after the forging, opposing side surfaces of the metal strip in a direction perpendicular to both the stacking direction and the up-down direction are arcuate surfaces, and the two opposite outer side surfaces of the probe in the stacking direction are both flat.

Further, each metal strip comprises at least one stopping portion which is spaced apart from the flattened portion are disposed along the up-down direction, and the stopping portions of the plurality of metal strips aligned in the stacking direction are welded together.

Further, each metal strip comprises a notch that extends in a direction perpendicular to both the stacking direction and the up-down direction, and each metal strip comprises two stopping portions, the two stopping portions are respectively disposed adjacent to a top portion and a bottom portion of the notch.

Compared with the prior art, the present invention comprises the following advantageous effects:

By stacking the plurality of metal strips along the horizontal direction and welding the plurality of metal strips together at their upper ends, at their lower ends, or at both ends, a multi-layer structured probe is formed, which reduces the shear stress and features a simple process and lower cost. By recessing the flattened portion on one side of the metal strip by a forging process, the gap is formed between the flattened portion and the adjacent metal strip, which makes it easy to control the size of the gap. This method can reduce the stiffness of the probe and thus achieve the effect of reducing the contact force without requiring laser cutting to form the gap. This results in a simple and easily implementable process.

The present invention further provides a test head, comprising at least one upper guide plate, wherein the upper guide plate is provided with at least one upper receiving hole; at least one lower guide plate, wherein the lower guide plate is provided with at least one lower receiving hole; a receiving space disposed between the upper guide plate and the lower guide plate; at least one probe received in the at least one upper receiving hole and the at least one lower receiving hole, wherein the probe includes a plurality of metal strips stacked and welded together along a horizontal direction, wherein each metal strip extends longitudinally along an up-down direction, and wherein upper ends, lower ends, or both ends of the metal strips are welded together; wherein each metal strip comprises a non-welding region disposed between the upper end and the lower end, and at least one portion of the non-welding region is disposed within the receiving space; wherein the upper receiving hole and the lower receiving hole are offset from each other along the horizontal direction; and wherein, during testing, at least one lower end of the metal strips engages with a device under test (DUT) downwardly, and the upper end of at least one of the metal strips engages with a contact element upwardly; wherein the non-welding region deforms within the receiving space.

Further, the metal strip is a cylindrical metal wire prior to forging, and after the forging, opposing side surfaces of the metal strip in a direction perpendicular to both the stacking direction and the up-down direction are arcuate surfaces, and the two opposite outer side surfaces of the probe in the stacking direction are flat surfaces.

Further, at least one of the metal strips comprises at least one flattened portion in the non-welding region, wherein the flattened portion is formed by forging and recessed in the stacking direction, thereby defining a gap between it and an adjacent metal strip.

Further, the probe comprises two beveled surfaces oppositely disposed in a direction perpendicular to both the stacking direction and the up-down direction, wherein the two beveled surfaces are located above the upper guide plate, and extend gradually toward each other in the up-down direction away from the flattened portion.

Further, the probe comprises two connecting surfaces and a contact tip, wherein each connecting surface connects the two beveled surfaces, the contact tip is disposed between the two connecting surfaces along the stacking direction, the contact tip protrudes upwardly relative to the connecting surfaces, and the contact tip is configured to engage with the contact element upwardly.

Further, the lower guide plate comprises two plates provided, spaced apart from each other in the up-down direction, the lower guide plate defined to be above is a first lower guide plate, and the lower guide plate defined to be below is a second lower guide plate, and a gap exists between two adjacent metal strips in the non-welding region, wherein the gap extends downwardly from above the first lower guide plate to below the first lower guide plate and is located above the second lower guide plate.

Further, the upper guide plate comprises two plates provided, spaced apart from each other in the up-down direction, the upper guide plate defined to be above is a first upper guide plate, and the upper guide plate defined to be below is a second upper guide plate; wherein the metal strip comprises a notch that extends in a direction perpendicular to both the stacking direction and the up-down direction, and the metal strip defines stopping portions respectively adjacent to a top portion and a bottom portion of the notch, and the stopping portions of the plurality of metal strips aligned in the stacking direction are welded together; wherein the first upper guide plate is located above the notch, the second upper guide plate is located between the top portion and the bottom portion, and the stopping portions are configured to stop the second upper guide plate from excessive displacement in the up-down direction.

Further, the plurality of metal strips of each probe include at least one first metal strip and at least one second metal strip, wherein the first metal strip and the second metal strip each include at least one high-conductivity layer and at least one high-hardness layer stacked to each other along the horizontal direction; wherein the upper end of the first metal strip and the upper end of the second metal strip adjacent to the first metal strip in the stacking direction are welded together, and the lower end of the first metal strip and the lower end of the second metal strip adjacent to the first metal strip in the stacking direction are welded together; and wherein the first metal strip and the adjacent second metal strip each comprise the non-welding region between their respective upper and lower ends, the non-welding regions not being welded to each other.

Further, the high-conductivity layer is the base material corresponding to the metal strip, and its material is a single alloy, and the material of the high-hardness layer is an alloy formed by one or a combination of at least two of palladium (Pd), nickel (Ni), and cobalt (Co).

Further, the high-hardness layer overlies and adheres to the corresponding high-conductivity layer over its entire area, the high-hardness layer being formed by a coating process.

Further, the first metal strip and the second metal strip each further include at least one anti-oxidation layer, the material of the anti-oxidation layer is gold, and the anti-oxidation layer is disposed on the corresponding high-hardness layer and is fully bonded thereto.

The present invention further provides a method for manufacturing a test head, comprising: Step (a), providing at least two metal sheets, wherein each metal sheet is provided with at least one high-conductivity layer and at least one high-hardness layer arranged along a front-rear direction; Step (b), stacking the at least two metal sheets with each other in the front-rear direction, and forming at least one welding region on the stacked metal sheets, wherein the metal sheets are welded to each other in the welding region; Step (c), cutting the at least two welded metal sheets along the front-rear direction to form at least one probe having a predetermined profile, wherein the at least one welding region is disposed at one of the two ends of the at least one probe, and a non-welding region is formed between the two ends; Step (d), providing an upper guide plate and a lower guide plate that are spaced apart in an up-down direction, and inserting at least one the probe into the upper guide plate and the lower guide plate along the up-down direction; and Step (e), moving horizontally at least one of the upper guide plate and the lower guide plate, such that the upper guide plate is offset from the lower guide plate along a left-right direction, wherein the non-welding region is bent between the upper guide plate and the lower guide plate.

Further, in Step (b), the at least one welding region is formed by welding the mutually stacked metal sheets using a resistance welding method.

Further, in Step (c), two welding regions are patterned in the metal sheet such that each individual probe cut therefrom includes a welding region at both ends.

Further, in Step (c), multiple probes are formed and arranged side by side by cutting, and one of the two ends of the at least one probe is connected to the metal sheet, while the other end is severed from the metal sheet; and in Step (d), at least some of the multiple probes connected to the metal sheet are collectively inserted into the upper guide plate after which the connections between the probes and the metal sheet are severed.

Further, in Step (a), at least two base materials of a high-conductivity material are provided, the base material is defined as the high-conductivity layer, and a high-hardness layer is plated on at least one of the front and rear sides of each high-conductivity layer, thereby forming the metal sheet.

Compared with the prior art, the present invention comprises the following advantageous effects:

By stacking and welding the plurality of metal strips along the horizontal direction, a probe comprising a multi-layer structure is formed, which results in a simple and easily implementable process and facilitates assembly into the upper guide plate and lower guide plate of the test head. Furthermore, by disposing the non-welding region between the upper end and the lower end of each metal strip, the non-welding regions between adjacent layers of the probe's multi-layer structure cannot withstand shear force. This effectively reduces the stiffness (rigidity) of the probe and decreases the contact force when the probe contacts the device under test (DUT). This means the reduction in probe stiffness, and thus the reduction in contact force, can be achieved without resorting to the method of forming apertures by laser cutting, which significantly reduces the manufacturing cost of the probe.

### BRIEF DESCRIPTION OF THE DRAWINGS

All of the objects and advantages of the present invention will become apparent from the following description of the accompanying drawings, which disclose several embodiments of the present invention. It should be understood that the drawings are used for purposes of illustration only, and not as a definition of the invention.

FIG. 1 is a partial cross-sectional view of a test head according to a first embodiment of the present invention before mating with a contact element and a device under test (DUT).

FIG. 2 is a partial perspective view of the test head of FIG. 1, with the partition plate concealed and showing only one probe for illustrative purposes.

FIG. 3 is an enlarged view of detail A in FIG. 2.

FIG. 4 is an enlarged view of detail B in FIG. 2.

FIG. 5 is a front view of the probe of FIG. 2 fully assembled into the upper guide plate and the lower guide plate.

FIG. 6 is a cross-sectional view taken along line C-C in FIG. 5.

FIG. 7 is a cross-sectional view taken along line D-D in FIG. 5.

FIG. 8 is an enlarged view of detail E in FIG. 5.

FIG. 9 is a partial cross-sectional view of the test head of FIG. 1 after mating with the contact element and the device under test.

FIG. 10 is a partial cross-sectional view of a test head according to a second embodiment of the present invention before mating with a contact element and a device under test.

FIG. 11 is a perspective view showing only one probe of FIG. 10.

FIG. 12 is a cross-sectional view taken along line F-F in FIG. 11.

FIG. 13 is a schematic view illustrating a manufacturing method for the probe shown in FIG. 10.

FIG. 14 is a schematic view of the metal sheets of FIG. 13 after stacking and cutting the predetermined shape of the probe.

### DETAILED DESCRIPTION OF THE PREFERRED EMBODIMENTS

For a better understanding of the object, structure, and features of the present invention, the present invention defines an up-down direction Z, a left-right direction X, and a front-rear direction Y, wherein these three directions are mutually perpendicular to each other. The present invention will be further described in conjunction with the accompanying drawings and specific embodiments.

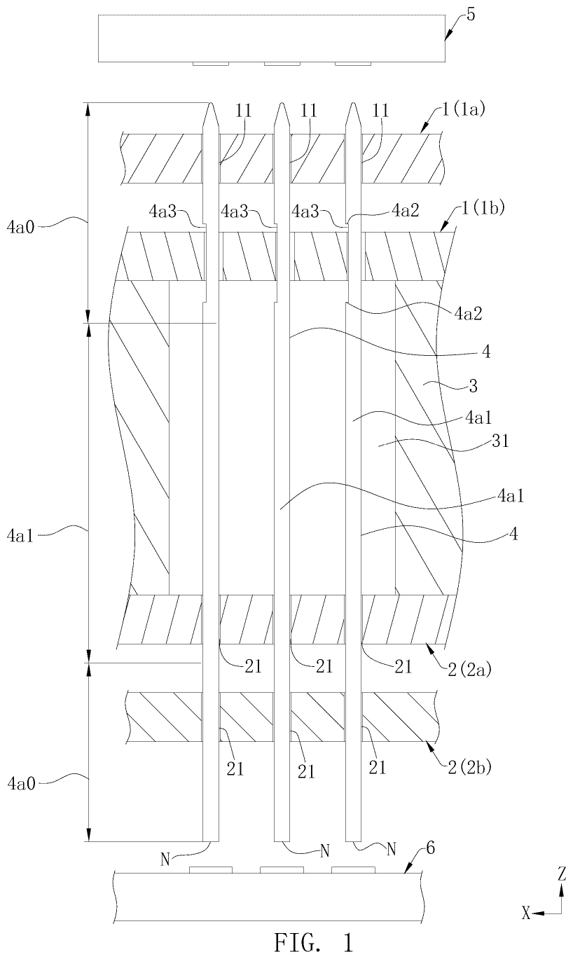

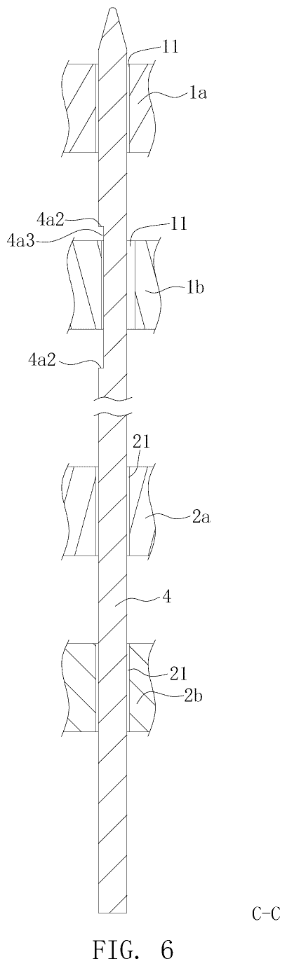

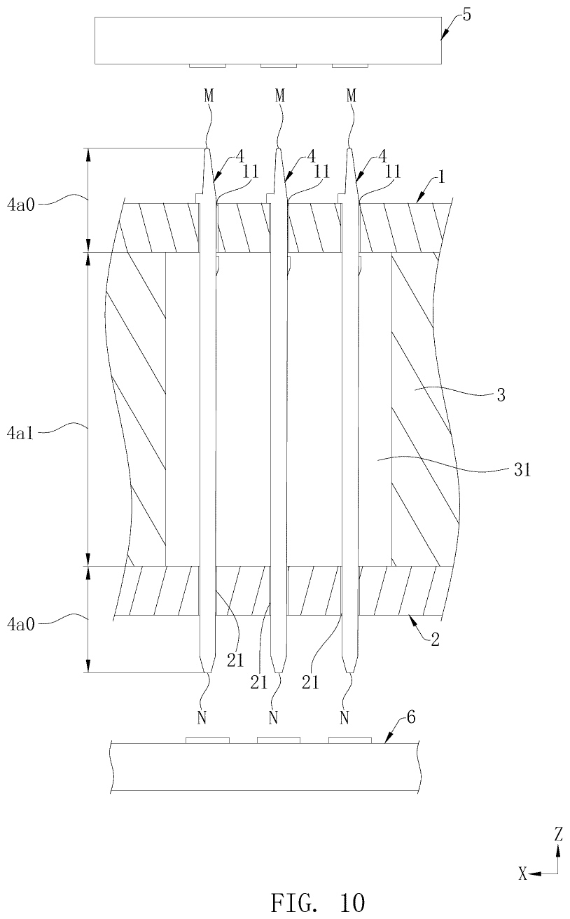

As shown in FIGS. 1 to 9, a first embodiment of the test head of the present invention is provided. As shown in FIGS. 10 to 14, a second embodiment of the test head of the present invention is provided. The test head in both embodiments includes at least one upper guide plate 1, at least one lower guide plate 2, an intermediate partition plate 3 disposed between the upper guide plate 1 and the lower guide plate 2, and a plurality of probes 4. The probe 4 passes through the upper guide plate 1, the intermediate partition plate 3, and the lower guide plate 2. The probe 4 passes upwardly through the upper guide plate 1 to engage with a contact element 5 in the up-down direction, and passes downwardly through the lower guide plate 2 to engage with a device under test (DUT) 6 downwardly. In both embodiments, the contact element 5 is a circuit board, and the DUT 6 is a chip. The accompanying drawings only show three of the probes 4 for illustration, but the test head actually contains more than three probes 4.

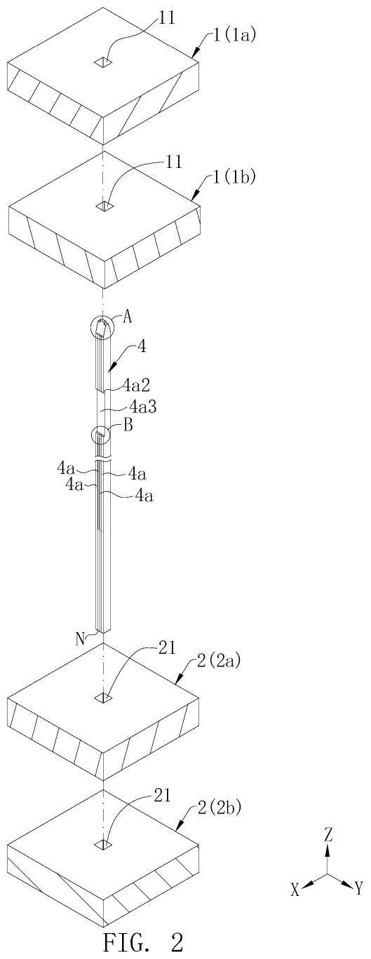

As shown in FIGS. 1 and 2, in the first embodiment, the number of the upper guide plate 1 and the lower guide plate 2 is two, respectively. The two upper guide plates 1 are disposed opposite to each other along the up-down direction Z and are both located above the partition plate 3. The upper guide plate 1 defined to be above is a first upper guide plate 1a, and the other (i.e., the lower) upper guide plate 1 is a second upper guide plate 1b. The first upper guide plate 1a and the second upper guide plate 1b are disposed spaced apart from each other in the up-down direction. The second upper guide plate 1b engages with the partition plate 3 downwardly. The first upper guide plate 1a and the second upper guide plate 1b both comprise a plurality of upper receiving holes 11 penetrating in the up-down direction. Each upper receiving hole 11 is provided for a corresponding probe 4 to pass through. Of course, in other embodiments, the number of the upper guide plate 1 may comprise only 1, or more than 2.

As shown in FIGS. 1 and 2, the two lower guide plates 2 are disposed opposite to each other along the up-down direction Z and are both located below the partition plate 3. The lower guide plate 2 defined to be above is a first lower guide plate 2a, and the other (i.e., the lower) lower guide plate 2 is a second lower guide plate 2b. The first lower guide plate 2a and the second lower guide plate 2b are spaced apart in the up-down direction. The first lower guide plate 2a engages with the partition plate 3 upwardly, meaning the partition plate 3 is vertically adjacent to the second upper guide plate 1b and the first lower guide plate 2a. The first lower guide plate 2a and the second lower guide plate 2b both comprise a plurality of lower receiving holes 21 penetrating in the up-down direction. Each lower receiving hole 21 is provided for one probe 4 to pass through. Before and during the process of assembling the probe 4 into the test head, the two upper guide plates 1 and the two lower guide plates 2 are disposed vertically aligned with each other (not shown). Therefore, the plurality of upper receiving holes 11 and the plurality of lower receiving holes 21 are disposed vertically aligned with each other (not shown), and the plurality of probes 4 are one-to-one received in the plurality of upper receiving holes 11 and the plurality of lower receiving holes 21. Of course, in other embodiments, the lower guide plate 2 may be provided with a single guide or more than two guides.

As shown in FIG. 1, the partition plate 3 comprises a receiving space 31 penetrating the partition plate 3 in the up-down direction (in other embodiments, the receiving space 31 may also be a space enclosed by a plurality of support columns). The plurality of probes 4 are collectively received in the receiving space 31.

As shown in FIGS. 2, 4, and 7, the probe 4 is formed by stacking and welding together four metal strips 4a horizontally, creating a four-layer structure (compared with the scheme of monolithic forming the probe, the scheme of forming the probe by multi-layer stacking allows the material of each probe 4 in the stacking direction to be varied so as to meet functional requirements, such as the four metal strips 4a comprising different materials to improve the elasticity of the probe 4 in the stacking direction). In the present embodiment, the four metal strips 4a are stacked along the front-rear direction Y, and the front-rear direction Y is the stacking direction. In other embodiments, the number of metal strips 4a may be set to only 2, or 3, or greater than 4; the specific number of metal strips 4a is not limited here, as long as it is greater than or equal to 2. As used herein, the term ‘welding’ encompasses: (i) a metallurgical bond formed by melting at least a portion of the contacting metal strips 4a, which involves metallic bonding at the interface; and (ii) other welding methods for joining the metal strips that do not necessarily rely on such melting. Specifically, the four metal strips 4a are respectively formed by forging four corresponding metal wires. Prior to the first forging, each metal strip 4a is a cylindrical metal wire (not shown) extending longitudinally along the up-down direction Z. In other embodiments, the metal wire may comprise other shapes, and the metal strip 4a may also be formed by cutting a plate-like metal sheet. The two sides of the metal wire are forged along the front-rear direction Y, forming the metal strip 4a comprising flat surfaces on the front and rear sides and arcuate surfaces on the left and right sides. The four metal strips 4a after forging are stacked and welded along the front-rear direction Y. The probe 4 formed in this manner comprises a simple process, is easy to implement, and significantly reduces the production cost of the probe 4.

As shown in FIGS. 1 to 3, the upper end of each metal strip 4a is welded to the adjacent metal strip 4a, and the lower end of each metal strip 4a is also welded to the adjacent metal strip 4a. A welding region 4a0 is formed at the welding position on each metal strip 4a. During testing, the lower end of at least one of the metal strips 4a engages with the device under test (DUT) 6 downwardly, and the upper end of at least one of the metal strips 4a engages with the contact element 5 upwardly. In the present embodiment, the upper ends of the four metal strips 4a are welded together to collectively form an upper contact surface M, and the upper contact surface M is configured to engage with the contact element 5 upwardly. The lower ends of the four metal strips 4a are welded together to collectively form a lower contact surface N (in other embodiments, the upper ends of the plurality of metal strips 4a may be welded together while the lower ends are not, or the lower ends of the plurality of metal strips 4a may be welded together while the upper ends are not). The lower contact surface N is a flat surface configured to engage with the DUT 6 downwardly. In other embodiments, the upper ends of the plurality of metal strips 4a welded together may not all contact the contact element 5, and among the plurality of metal strips 4a, only a portion of the upper ends of the metal strips 4a contact the contact element 5 (e.g., the upper ends of the plurality of metal strips 4a welded together may be of unequal height); or, the lower ends of the plurality of metal strips 4a welded together may not all contact the DUT 6, and among the plurality of metal strips 4a, only a portion of the lower ends of the metal strips 4a contact the DUT 6 (e.g., the lower ends of the plurality of metal strips 4a welded together may be of unequal height).

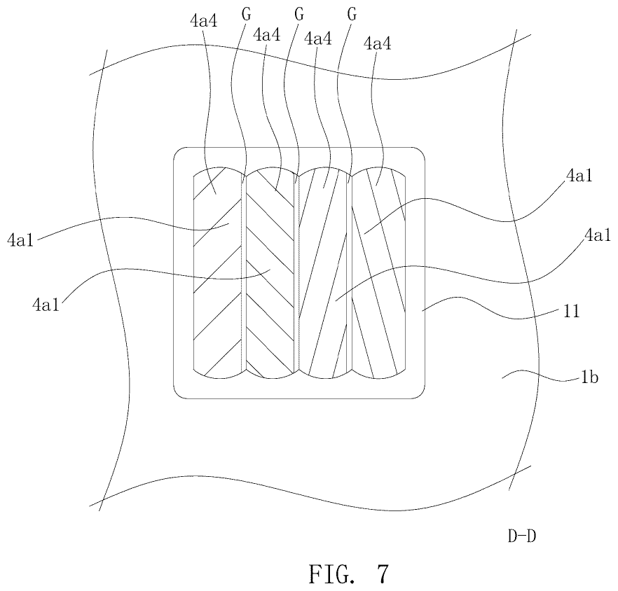

As shown in FIGS. 1, 2, and 4, each metal strip 4a comprises a non-welding region 4a1, two stopping portions 4a2, and a notch 4a3. The non-welding region 4a1 is defined as being located between the upper and the lower ends of the metal strip 4a in the up-down direction Z. Specifically, the non-welding region 4a1 is located between the second upper guide plate 1b and the second lower guide plate 2b in the up-down direction Z, and at least one portion of the non-welding region 4a1 is disposed within the receiving space 31. In the present embodiment, the non-welding region 4a1 extends downwardly from above the first lower guide plate 2a to below the first lower guide plate 2a and is located above the second lower guide plate 2b (refer to FIG. 7). In other embodiments, the non-welding region 4a1 may be entirely received within the receiving space 31 without extending to the first lower guide plate 2a. That is, both its length and its location in the up-down direction are variable.

As shown in FIGS. 2, 3, and 9, when the upper contact surface M engages with the contact element 5, and the lower contact surface N engages with the DUT 6, the non-welding region 4a1 of the probe 4 deforms within the receiving space 31. Since the probe 4 is formed by stacking multiple metal strips 4a to constitute a multi-layer structure, the non-welding regions 4a1 between adjacent layers of the probe 4 cannot withstand shear force, thereby enabling the reduction of the stiffness of the probe 4 and decreasing the contact force when the probe 4 contacts the DUT 6.

As shown in FIGS. 2, 4, and 6, the notch 4a3 is extended along a direction perpendicular to both the stacking direction Y and the up-down direction Z (i.e., along the left-right direction X). Each notch 4a3 comprises a top portion and a bottom portion oppositely disposed along the up-down direction Z. The two stopping portions 4a2 of each metal strip 4a are oppositely disposed along the up-down direction and are respectively disposed on the top portion and the bottom portion of the corresponding notch 4a3. The stopping portion 4a2 is configured to prevent excessive displacement of the second upper guide plate 1b in the up-down direction. The plurality of stopping portions 4a2 of the plurality of metal strips 4a located on the same side of the notch 4a3 in the up-down direction are welded together. The plurality of notches 4a3 are arranged connected along the front-rear direction Y. In other embodiments, the stopping portion 4a2 may be a protrusion extending out from the metal strip 4a along the left-right direction X.

As shown in FIG. 1, the first upper guide plate 1a is located above the notch 4a3. After all the probes 4 have been inserted, at least one of the upper guide plate 1 and the lower guide plate 2 is moved horizontally such that the plurality of upper receiving holes 11 of the upper guide plate 1 are offset from the corresponding plurality of lower receiving holes 21 of the lower guide plate 2 along the horizontal direction (i.e., the upper receiving hole 11 and the lower receiving hole 21 are not vertically aligned). The second upper guide plate 1b is snap-fitted into the notch 4a3 along the left-right direction via a slight misalignment, thereby locking the probe 4 to prevent the probe 4 from escaping, i.e., preventing the probe 4 from falling along the up-down direction Z.

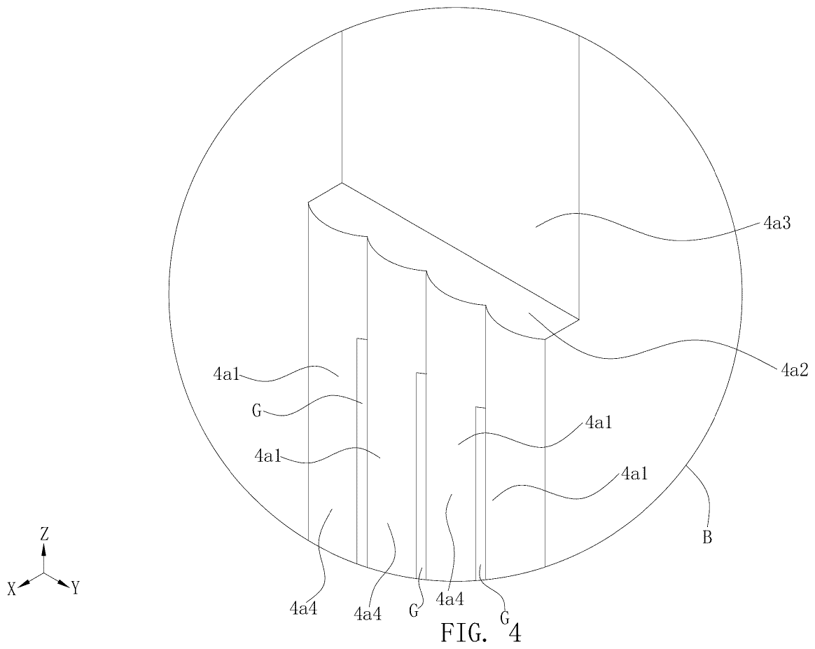

As shown in FIGS. 4 to 6, the second upper guide plate 1b is located between the top portion and the bottom portion of the notch 4a3. The top portion of the notch 4a3 is configured to block the second upper guide plate 1b downward, thereby preventing excessive upward displacement of the second upper guide plate 1b. The bottom portion of the notch 4a3 is configured to block the second upper guide plate 1b upward, thereby preventing excessive downward displacement of the second upper guide plate 1b from.

As shown in FIGS. 2 and 4, along the front-rear direction Y, except for the foremost one of the four metal strips 4a which is not provided with the flat portion 4a4, each of the remaining metal strips 4a is subjected to secondary forging on the side facing the foremost metal strip 4a in the front-rear direction Y, thereby forming a flat portion 4a4. The flattened portion 4a4 is disposed in the corresponding non-welding region 4a1. That is to say, along the recessing direction of the flattened portion 4a4, the 2nd, 3rd, and 4th metal strips 4a are each provided with one flattened portion 4a4, while the remaining 1st metal strip 4a is not provided with the flattened portion 4a4, meaning one metal strip 4a may not undergo the secondary forging.

As shown in FIGS. 2 and 4, except for the first metal strip 4a, whose opposite side surfaces are flat, only one side surface of the opposing side surfaces of each of the remaining metal strips 4a is flat, and the other side surface is provided with the flattened portion 4a4. In other embodiments, the specific number of metal strips 4a provided with the flattened portion 4a4 can be set according to actual requirements and is not specifically limited here. Furthermore, a plurality of flattened portions 4a4 that are spaced apart in the up-down direction may be provided on the same metal strip 4a, and the specific number of flattened portions 4a4 on the same metal strip 4a is not limited here.

As shown in FIGS. 2 and 4, the thickness of the flattened portion 4a4 along the stacking direction Y is less than the thickness of the welding portion of the metal strip 4a. A gap G exists between each adjacent pair of metal strips 4a in the non-welding region 4a1. Specifically, each flattened portion 4a4 forms a gap G with the adjacent metal strip 4a, the gap G partially spacing apart two adjacent metal strips 4a. In the present embodiment, due to the existence of the gap G, the plurality of metal strips 4a of the probe 4 are welded together in the up-down direction Z except at the non-welded region 4a1, such that the remaining portions are welded. Accordingly, the probe 4 is formed in a configuration in which the upper and lower ends are joined and fixed, while the middle portion is in a state where the four metal strips 4a are independently spaced apart. In other embodiments, the non-welding region 4a1 may be formed without the flattened portion 4a4, meaning that the adjacent two metal strips 4a are stacked and welded together after each metal strip 4a is formed only by a single forging process, and the non-welding regions 4a1 of two adjacent metal strips 4a may contact each other rather than being formed with a gap.

As shown in FIGS. 2 and 4, the dimension of the gap G in the front-rear direction Y is 0.002 mm. In other embodiments, the dimension of the gap G may be greater than or less than 0.002 mm. When the metal strip 4a is subjected to secondary forging, the depth of forging can be controlled according to actual requirements, thereby allowing adjustment of the dimension of the gap G in the front-rear direction Y. The depth of secondary forging for each metal strip 4a may be the same or different, meaning the dimensions of the gap G in the front-rear direction Y can be set to be the same or different.

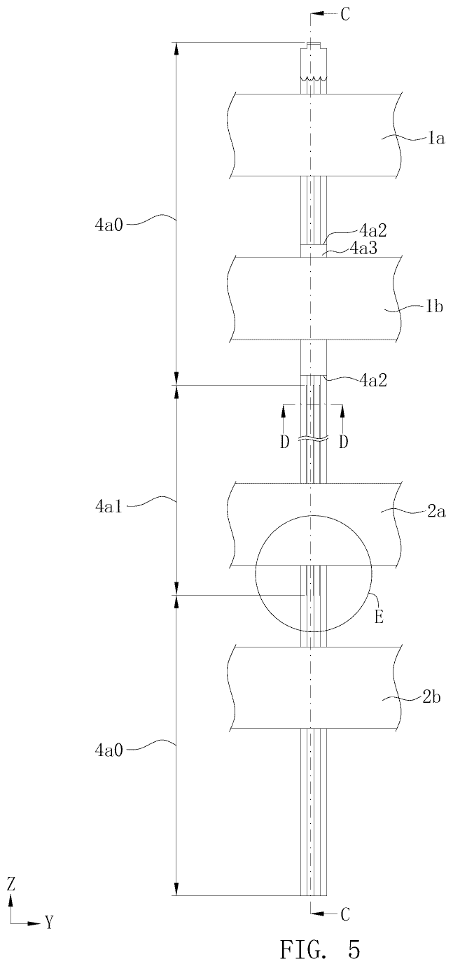

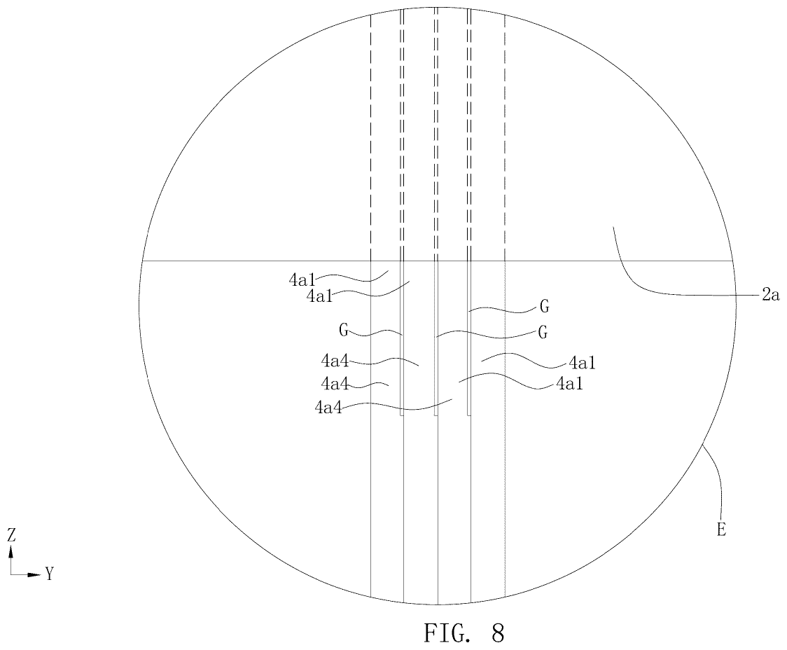

As shown in FIGS. 5 and 8, each gap G extends downwardly from above the first lower guide plate 2a to below the first lower guide plate 2a and is located above the second lower guide plate 2b. In other embodiments, the gap G may extend to above the first lower guide plate 2a, or it may extend to below the second lower guide plate 2b. The specific position of the gap G along the up-down direction Z of the probe 4 is not limited here, meaning the length of the gap G can be adjusted according to actual requirements.

The forming method for the probe 4 in the present embodiment is as follows:
1. The cylindrical metal wire extending longitudinally in the up-down direction Z is subjected to a forging process on both sides in the front-rear direction Y to form the metal strip 4a comprising arcuate left and right surfaces and flat front and rear surfaces.
2. One side of the front and rear surfaces of the metal strip 4a is locally subjected to a secondary forging to form the metal strip 4a comprising the flattened portion 4a4.
3. A plurality of the metal strips 4a comprising the flattened portion 4a4 and one metal strip 4a without the flattened portion 4a4 are sequentially stacked along the front-rear direction Y, and the upper ends and the lower ends of the plurality of metal strips 4a are welded together, respectively, thereby forming the probe 4.

The method for manufacturing the probe 4 described above effectively resolves the high-cost issues (such as complex processes and raw material waste) associated with manufacturing probes using MEMS and laser cutting as mentioned in the prior art.

The forming method for the probe 4 in this embodiment can alternatively be:
1. The cylindrical metal wire extending longitudinally in the up-down direction Z is forged on both sides in the front-rear direction Y to form the metal strip 4a comprising arcuate left and right sides and flat front and rear sides.
2. The upper ends of the plurality of metal strips 4a are welded together using tin or silver, and the lower ends of the plurality of metal strips 4a are also welded together using tin or silver, thereby forming the probe 4. (Note: The term “welding” used in the present invention includes this type of soldering.)

The probe 4 manufactured in this manner, under the action of the solder (tin or silver), the welded portions protrude relative to the non-welding regions 4a1 due to the presence of solder. Therefore, even if the metal strip 4a is not subjected to secondary forging to form the flattened portion 4a4, a gap G will still exist between the non-welding region 4a1 of the two adjacent metal strips 4a. Of course, the non-welding regions 4a1 of the two adjacent metal strips 4a may also contact each other rather than being formed with a gap. That is, even without secondary forging, the gap G can also be formed using tin soldering or silver soldering. Furthermore, the non-welding region 4a1 of the probe 4 may also not comprise the gap (i.e.,

there is no gap in the area where the two adjacent metal strips 4a are not welded).

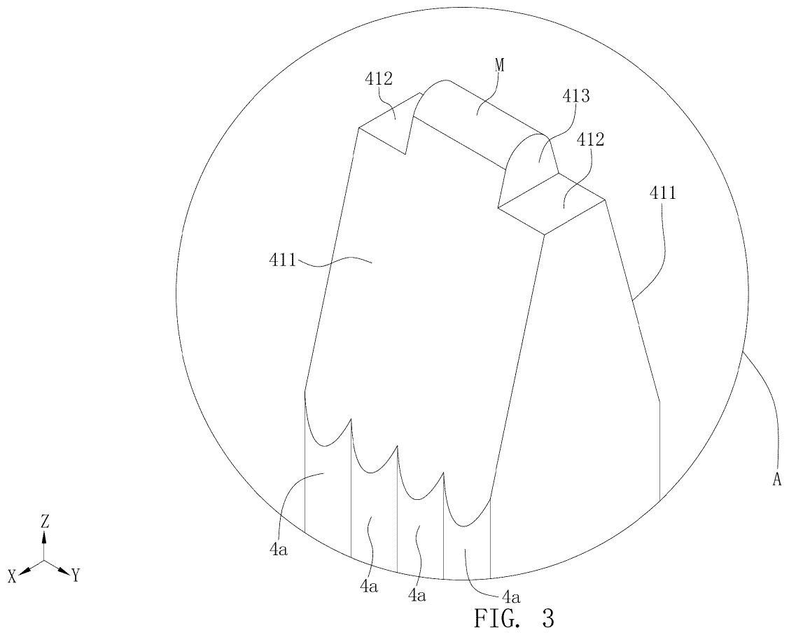

As shown in FIGS. 2 and 3, each probe 4 comprises two beveled surfaces 411, two connecting surfaces 412, and a contact tip 413. The two beveled surfaces 411 are oppositely disposed along the left-right direction X and are located above the first upper guide plate 1a, and they extend gradually toward each other in the up-down direction Z away from the flattened portion 4a4. The connecting surface 412 is a horizontally extending flat surface. The two connecting surfaces 412 are located at the same height of the probe 4 in the up-down direction Z and are spaced apart along the front-rear direction Y. Each connecting surface 412 connects the two beveled surfaces 411 along the left-right direction X. The contact tip 413 is formed to protrude upwardly relative to the two connecting surfaces 412 and is located between the two connecting surfaces 412 in the front-rear direction Y. It is configured to engage with the contact element 5 upwardly. This structure reduces the contact area where the contact tip 413 engages with the contact element 5, allowing the stress to be more concentrated.

The method for manufacturing the test head in the present embodiment includes:
Step (a): Providing a plurality of metal strips 4a extending longitudinally in the up-down direction, stacking the plurality of metal strips 4a with one another along the front-rear direction, wherein at least one of the upper end and the lower end of each metal strip 4a is welded to the adjacent metal strip 4a, and a gap G is formed between the pre-deformed portion of at least one of the metal strips 4a and the adjacent metal strip 4a.
Step (b): After Step (a), providing an upper guide plate 1 and a lower guide plate 2 that are spaced apart in the up-down direction, and inserting the plurality of metal strips 4a welded together into the upper guide plate 1 and the lower guide plate 2 along the up-down direction.
Step (c): After Step (b), moving horizontally at least one of the upper guide plate 1 and the lower guide plate 2, such that the upper guide plate 1 is offset from the lower guide plate 2 along the left-right direction, resulting in the bending and deformation of the non-welding region of the probe (as previously described).

Prior to Step (a), a plurality of cylindrical metal wires are provided, and both sides of each metal wire are forged along the front-rear direction to form the metal strip 4a comprising flat surfaces on the front and rear sides.

In the present embodiment, before stacking the plurality of metal strips 4a with each other along the front-rear direction, a pre-deformed portion of at least one of the metal strips 4a, on either the front or rear side, is forged to form the flattened portion 4a4. This ensures that, after the plurality of metal strips 4a are stacked, the gap G is formed between the flattened portion 4a4 and the adjacent metal strip 4a.

The metal strip 4a in the above Step (a) can be a regular cuboid or an irregular structure, as long as the plurality of metal strips 4a can be stacked with each other along the front-rear direction. The specific shape of the metal strip 4a is not limited here. The pre-deformed portion refers to the portion that will undergo bending deformation when the probe 4 is manufactured and contacts the device under test (DUT) 6 and is subjected to force.

The advantage of the method for manufacturing the test head of the present invention is that, in addition to the aforementioned benefits of low manufacturing cost for the probe 4 and effective stress reduction, it also allows for flexible control over the size of the gap G, thereby adjusting the rigidity or contact stress of the probe 4.

As shown in FIGS. 10 to 14, a second embodiment of the test head of the present invention is provided. In this embodiment, the number of the upper guide plate 1 and the lower guide plate 2 is set to one respectively. The partition plate 3 comprises a receiving space 31 penetrating by the partition plate 3 in the up-down direction.

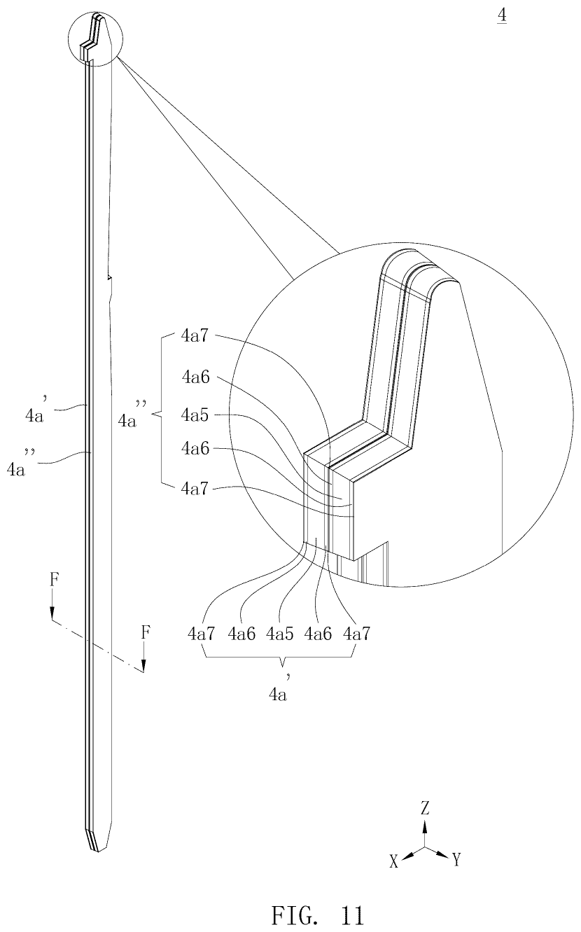

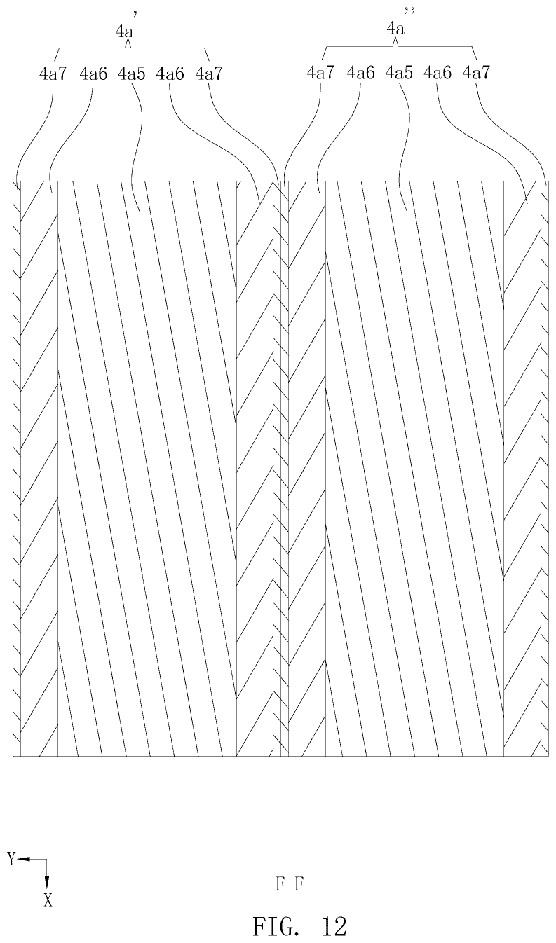

As shown in FIGS. 11 and 12, the probe 4 is composed of two sheet-like metal strips 4a. Each metal strip 4a extends longitudinally along the up-down direction Z. The two metal strips 4a are stacked and welded together along the horizontal direction, thereby forming the probe 4 with a multi-layer structure. The two metal strips 4a are stacked along the front-rear direction Y. A welding region 4a0 is formed at the welding position on each metal strip 4a. The welding may be a bond resulting from the melting of the metal strips 4a, whereby they are joined by metallic bonding, or it may be soldering. One of the metal strips 4a is defined as a first metal strip 4a′, and the other metal strip is defined as a second metal strip 4a″. The upper end of the first metal strip 4a′ is welded to the upper end of the second metal strip 4a″. At least one upper end of the metal strips 4a engages with the contact element 5 upwardly. In this embodiment, the upper ends of the two metal strips 4a are welded together to collectively form an upper contact surface M, which is configured to engage with the contact element 5 upwardly. The lower end of the first metal strip 4a′ is also welded to the lower end of the second metal strip 4a″. The lower ends of the two metal strips 4a are welded together to collectively form a lower contact surface N (Of course, in other embodiments, the upper ends of the plurality of metal strips 4a may be welded together but the lower ends may not be, or the lower ends of the plurality of metal strips 4a may be welded together but the upper ends may not be). The lower contact surface N is a flat surface configured to engage with the device under test (DUT) 6 downwardly.

As shown in FIGS. 10 and 11, each metal strip 4a comprises a non-welding region 4a1, a high-conductivity layer 4a5, two high-hardness layers 4a6, and two anti-oxidation layers 4a7. In other embodiments, the metal strip 4a may also only be provided with one high-hardness layer 4a6 and one anti-oxidation layer 4a7. The non-welding region 4a1 is located along the up-down direction Z between the upper end and the lower end of the metal strip 4a. Specifically, the non-welding region 4a1 is located between the upper guide plate 1 and the lower guide plate 2 in the up-down direction Z, and at least one portion of the non-welding region 4a1 is disposed within the receiving space 31. In other embodiments, the non-welding region 4a1 may be entirely received in the receiving space 31.

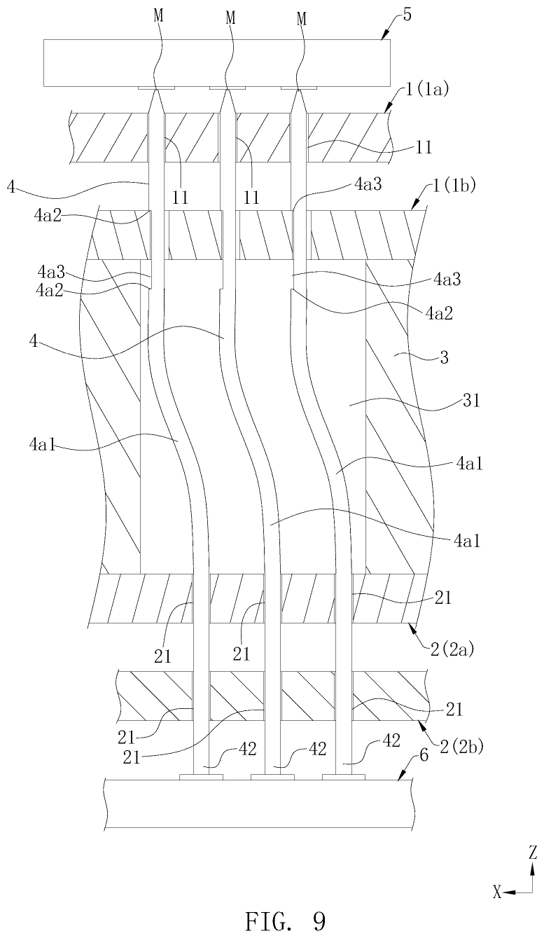

As shown in FIGS. 10 and 11,the principle for reducing the rigidity of the probe 4 in the second embodiment is the same as that of the first embodiment: Since the probe 4 is formed by stacking two metal strips 4a to constitute a multi-layer structure, the non-welding regions 4a1 between adjacent layers of the probe 4 cannot withstand shear force. This enables the reduction of the stiffness of the probe 4 and decreases the contact force when the probe 4 contacts the DUT 6. When the upper contact surface M engages with the contact element 5, and the lower contact surface N engages with the DUT 6, the non-welding region 4a1 of the probe 4 deforms within the receiving space 31 (refer to FIG. 9 of the first embodiment).

As shown in FIGS. 11 and 12, the high-conductivity layer 4a5 is the substrate of the metal strip 4a. The material of the substrate includes, but is not limited to, silver, copper, and gold. In the present embodiment, the substrate material is silver. However, in other embodiments, the substrate of the metal strip 4a may be a substantially homogeneous sheet made of a single alloy (i.e., the alloy sheet is typically a substantially homogeneous single alloy in its original state). In other embodiments, the probe 4 may be formed of more than two metal strips 4a.

As shown in FIGS. 11 and 12, the material of the high-hardness layer 4a6 is an alloy formed by one or a combination of at least two of palladium (Pd), nickel (Ni), and cobalt (Co). The two high-hardness layers 4a6 are respectively located on the front and rear sides of the high-conductivity layer 4a5. The high-hardness layer 4a6 is formed on the corresponding high-conductivity layer 4a5 by a coating process and is fully bonded thereto. That is, the high-hardness layer 4a6 fully adheres to and covers the front and rear sides of the high-conductivity layer 4a5. The coating process includes, but is not limited to, one or more of electroplating, electroless plating, Physical Vapor Deposition (PVD), and Chemical Vapor Deposition (CVD). In the present embodiment, the high-hardness layer 4a6 is bonded to the high-conductivity layer 4a5 by electroplating.

As shown in FIGS. 11 and 12, the two anti-oxidation layers 4a7 are correspondingly disposed with the two high-hardness layers 4a6 along the front-rear direction, Along the front-rear direction, each anti-oxidation layer 4a7 is located on the outer side of the corresponding high-hardness layer 4a6. The anti-oxidation layer 4a7 is formed on the corresponding high-hardness layer 4a6 by a coating process and is fully bonded thereto. The material of the anti-oxidation layer 4a7 is gold (Au).

The method for manufacturing the test head in the present embodiment includes:
Step (a): Providing at least two metal sheets 7. Each metal sheet 7 is provided with at least one high-conductivity layer 4a5 and at least one high-hardness layer 4a6 arranged along the front-rear direction.
Step (b): Stacking the at least two metal sheets 7 with each other in the front-rear direction, and forming at least one welding region 4a0 on the mutually stacked metal sheets 7, wherein the metal sheets are welded to each other in the welding region.
Step (c): Cutting the at least two welded metal sheets 7 along the front-rear direction to form the probe 4 having a predetermined profile. The welding region is disposed at one of the two ends of the at least one probe 4, and a non-welding region 4a1 is formed between the two ends.
Step (d): Providing an upper guide plate 1 and a lower guide plate 2 that are spaced apart in the up-down direction, and inserting the at least one probe 4 through the upper guide plate 1 and the lower guide plate 2 along the up-down direction.
Step (e): Moving horizontally at least one of the upper guide plate 1 and the lower guide plate 2, such that the upper guide plate 1 is offset from the lower guide plate 2 along the left-right direction. The non-welding region 4a1 is thereby bent between the upper guide plate 1 and the lower guide plate 2.

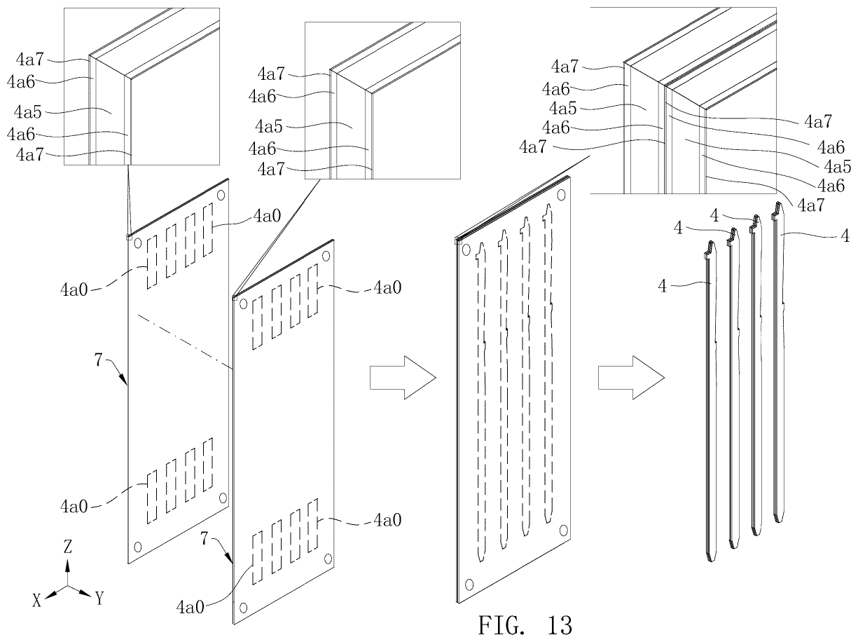

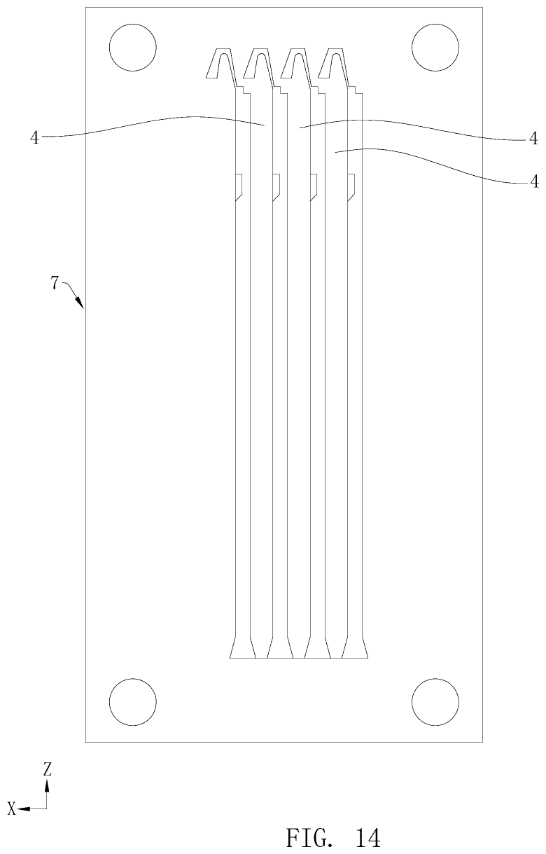

As shown in FIGS. 13 and 14, in Step (a) of this embodiment, at least two substrates of high-conductivity material are provided and defined as the high-conductivity layer 4a5. The high-hardness layers 4a6 are plated on both the front and rear sides of each high-conductivity layer 4a5, thereby forming the metal sheet 7. In Step (a), each metal sheet 7 is further plated with two anti-oxidation layers 4a7. The number of the metal sheets 7 is 2, and the number of the high-hardness layers 4a 6 is also 2. In other embodiments, the anti-oxidation layer 4a7 may not be provided; the number of the metal sheets 7 may be greater than 2; and the number of the high-conductivity layer 4a5, the high-hardness layer 4a6, and the anti-oxidation layer 4a7 can be set according to actual needs as long as there is at least one layer of each.

As shown in FIGS. 13 and 14, in Step (b), the stacked metal sheets 7 are welded together by resistance welding to form a plurality of welding regions 4a0. In Step (c), two welding regions 4a0 are patterned in the metal sheet 7 such that each individual probe 4 cut therefrom includes a welding region 4a0 at both ends. In Step (c), multiple probes 4 are arranged side by side by cutting, and one end of the two ends of the probe 4 is connected to the metal sheet 7, while the other end is severed from the metal sheet 7. In Step (d), at least some of the multiple probes 4 connected to the metal sheet 7 are collectively inserted into the upper guide plate 1 and the lower guide plate 2, and then the connection between the probe 4 and the metal sheet 7 is severed after the probes are inserted into the upper guide plate 1 and the lower guide plate 2.

The probe 4 in the first embodiment may also comprise the high-conductivity layer 4a5, the high-hardness layer 4a6, and the anti-oxidation layer 4a7. Furthermore, the probe 4 may be obtained by the manufacturing method of the second embodiment, and the probe 4 may be assembled into the test head formed by the upper guide plate 1 and the lower guide plate 2.

In summary, the probe, the test head including the probe, and the method for manufacturing the test head of the present invention provide the following advantageous effects:
1. By stacking a plurality of metal strips 4a along the horizontal direction and welding together at their upper ends, at their lower ends, or at both ends (because the pitch of the contact points is very small, and without welding, the metal strips 4a might loosen and spread, causing the probe 4 to contact multiple points simultaneously, and possibly preventing smooth passage by the upper guide plate 1 or the lower guide plate 2), a multi-layer structured probe 4 is formed. This process is simple and reduces raw material waste, thereby lowering the cost. Furthermore, forming the flattened portion 4a4 recessed on one side of the metal strip 4a by a forging process means the gap G can be formed without laser cutting. This process is simple, easy to implement, and significantly reduces the manufacturing cost of the probe 4. Moreover, the forging process allows for flexible adjustment of the size of the gap G.
2. By providing the contact tip 413, the contact area between the contact tip 413 and the contact element 5 is reduced, resulting in more concentrated stress.
3. By providing the flattened portion 4a4, the formed gap G is extended along the up-down direction Z to below the first lower guide plate 2a and above the second lower guide plate 2b. This increases the extension length of the gap G in the up-down direction Z, thereby increasing the overall elasticity of the probe 4 and reducing the contact force exerted by the probe 4 on the device under test 6.
4. By stacking a plurality of metal strips 4a along the horizontal direction and welding the plurality of metal strips 4a together at their upper ends, at their lower ends, or at both ends, while disposing the non-welding region 4a1 between the upper and lower ends of each metal strip 4a, a multi-layer structured probe 4 is formed. The process is simple and easy to implement. Since the non-welding regions 4a1 between adjacent layers cannot withstand shear force, the stiffness of the probe 4 is reduced, thereby decreasing the contact force when the probe 4 contacts the device under test 6. This achieves the effect of reducing contact force of the probe 4

without needing laser cutting to form apertures, significantly lowering the manufacturing cost of the probe 4.
5. By simultaneously providing the high-hardness layer 4a6 and the high-conductivity layer 4a5 in the first metal strip 4a′ and the second metal strip 4a″, the invention utilizes the high-hardness material to ensure the structural strength and wear resistance of the probe 4, resisting wear caused by repeated testing and greatly extending the service life of the probe 4 tip. At the same time, the high-conductivity material ensures current transmission, solving the contradiction where a single material cannot meet all performance requirements.
6. Due to the simple process of manufacturing the probe 4 by stacking the metal strips 4a, and the effective reduction of cost and contact stress achieved by providing the non-welding region 4a1, the test head, formed by assembling the probe 4 into the upper guide plate 1, the lower guide plate 2, and the intermediate partition plate 3, is beneficial for extending the service life of the test head and reducing its production cost.
7. By stacking at least two metal sheets 7 comprising the high-conductivity layer 4a5 and the high-hardness layer 4a6, welding and then cutting to form the probe 4, the high conductivity and mechanical strength of the probe 4 are increased. Furthermore, disposing the welding region 4a0 at one end of the probe 4, and forming the non-welding region 4a1 between the two ends, the non-welding region 4a1 reduces the contact stress of the probe 4. Assembling the plurality of probes 4 into the upper guide plate 1, the lower guide plate 2, and the intermediate partition plate 3 forms the test head that extends service life and reduces production cost.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A probe, comprising:
A plurality of metal strips stacked and welded together along a horizontal direction, wherein each metal strip extends longitudinally along an up-down direction, and wherein at least one of the metal strips comprises at least one flattened portion that is formed by forging and recessed in a stacking direction, such that a gap is formed between the flattened portion and an adjacent metal strip, wherein upper ends, lower ends, or both ends of the metal strips are welded together, and wherein, during testing, the lower end of at least one of the metal strips engages with a device under test (DUT) downwardly, and the upper end of at least one of the metal strips engages with a contact element upwardly.

2. The probe as claimed in claim 1, wherein the metal strip is a cylindrical metal wire prior to the forging, and after the forging, opposing side surfaces of the metal strip in a direction perpendicular to both the stacking direction and the up-down direction are arcuate surfaces, and wherein the two opposite outer side surfaces of the probe in the stacking direction are both flat surfaces.

3. The probe as claimed in claim 1, wherein each metal strip comprises at least one stopping portion which is spaced apart from the flattened portion along the up-down direction, and wherein the stopping portions of the plurality of metal strips aligned in the stacking direction are welded together.

4. The probe as claimed in claim 3, wherein each metal strip comprises a notch that extends in a direction perpendicular to both the stacking direction and the up-down direction, and each metal strip comprises two stopping portions, the two stopping portions are respectively disposed adjacent to a top portion and a bottom portion of the notch.

5. A test head, comprising:
at least one upper guide plate, wherein the upper guide plate is provided with at least one upper receiving hole;
at least one lower guide plate, wherein the lower guide plate is provided with at least one lower receiving hole;
a receiving space disposed between the upper guide plate and the lower guide plate; and
at least one probe received in the at least one upper receiving hole and the at least one lower receiving hole, wherein the at least one probe includes a plurality of metal strips stacked and welded together along a horizontal direction, wherein each metal strip extends longitudinally along an up-down direction, and wherein upper ends, lower ends, or both ends of the metal strips are welded together; wherein each metal strip comprises a non-welding region disposed between the upper end and the lower end, and at least one portion of the non-welding region is disposed within the receiving space; wherein the upper receiving hole and the lower receiving hole are offset from each other along the horizontal direction; and wherein, during testing, at least one lower end of the metal strips engages with a device under test downwardly, and at least one upper end of the metal strips engages with a contact element upwardly; wherein the non-welding region deforms within the receiving space.

6. The test head as claimed in claim 5, wherein the metal strip is a cylindrical metal wire prior to forging, and after the forging, opposing side surfaces of the metal strip in a direction perpendicular to both the stacking direction and the up-down direction are arcuate surfaces, and wherein the two opposite outer side surfaces of the probe in the stacking direction are flat surfaces.

7. The test head as claimed in claim 5, wherein at least one of the metal strips comprises at least one flattened portion in the non-welding region, wherein the flattened portion is formed by forging and recessed in the stacking direction, thereby defining a gap between it and an adjacent metal strip.

8. The test head as claimed in claim 7, wherein the probe comprises two beveled surfaces oppositely disposed in a direction perpendicular to both the stacking direction and the up-down direction, wherein the two beveled surfaces are located above the upper guide plate, and extend gradually toward each other in the up-down direction away from the flattened portion.

9. The test head as claimed in claim 8, wherein the probe comprises two connecting surfaces and a contact tip, wherein each connecting surface connects the two beveled surfaces, the contact tip is disposed between the two connecting surfaces along the stacking direction, the contact tip protrudes upwardly relative to the connecting surfaces, and the contact tip is configured to engage with the contact element upwardly.

10. The test head as claimed in claim 5, wherein the lower guide plate comprises two plates provided, spaced apart from each other in the up-down direction, the lower guide plate defined to be above is a first lower guide plate, and the lower guide plate defined to be below is a second lower guide plate, and a gap exists between two adjacent metal strips in the non-welding region, wherein the gap extends downwardly from above the first lower guide plate to below the first lower guide plate and is located above the second lower guide plate.

11. The test head as claimed in claim 5, wherein the upper guide plate comprises two plates provided, spaced apart from each other in the up-down direction, the upper guide plate defined to be above is a first upper guide plate, and the upper guide plate defined to be below is a second upper guide plate; wherein the metal strip comprises a notch that extends in a direction perpendicular to both the stacking direction and the up-down direction, and the metal strip defines stopping portions respectively adjacent to a top portion and a bottom portion of the notch, and the stopping portions of the plurality of metal strips aligned in the stacking direction are welded together; wherein the first upper guide plate is located above the notch, the second upper guide plate is located between the top portion and the bottom portion, and the stopping portions are configured to stop the second upper guide plate from excessive displacement in the up-down direction.

12. The test head as claimed in claim 5, wherein the plurality of metal strips of each probe include at least one first metal strip and at least one second metal strip, wherein the first metal strip and the second metal strip each include at least one high-conductivity layer and at least one high-hardness layer stacked to each other along the horizontal direction; wherein the upper end of the first metal strip and the upper end of the second metal strip adjacent to the first metal strip in the stacking direction are welded together, and the lower end of the first metal strip and the lower end of the second metal strip adjacent to the first metal strip in the stacking direction are welded together; and wherein the first metal strip and the adjacent second metal strip each comprise the non-welding region between their respective upper and lower ends, the non-welding regions not being welded to each other.

13. The test head as claimed in claim 12, wherein the high-conductivity layer is the base material corresponding to the metal strip, and its material is a single alloy, and the material of the high-hardness layer is an alloy formed by one or a combination of at least two of palladium (Pd), nickel (Ni), and cobalt (Co).

14. The test head as claimed in claim 13, wherein the high-hardness layer overlies and adheres to the corresponding high-conductivity layer over its entire area, the high-hardness layer being formed by a coating process.

15. The test head as claimed in claim 12, wherein the first metal strip and the second metal strip each further include at least one anti-oxidation layer, the material of the anti-oxidation layer is gold, and the anti-oxidation layer is disposed on the corresponding high-hardness layer and is fully bonded thereto.

16. A method for manufacturing a test head, comprising:
Step (a), providing at least two metal sheets, wherein each metal sheet is provided with at least one high-conductivity layer and at least one high-hardness layer arranged along a front-rear direction;
Step (b), stacking the at least two metal sheets with each other in the front-rear direction, and forming at least one welding region on the stacked metal sheets, wherein the metal sheets are welded to each other in the welding region;
Step (c), cutting the at least two welded metal sheets along the front-rear direction to form at least one probe having a predetermined profile, wherein the at least one welding region is disposed at one of the two ends of the at least one probe, and a non-welding region is formed between the two ends;
Step (d), providing an upper guide plate and a lower guide plate that are spaced apart in an up-down direction, and inserting the at least one probe through the upper guide plate and the lower guide plate along the up-down direction; and
Step (e), moving horizontally at least one of the upper guide plate and the lower guide plate, such that the upper guide plate is offset from the lower guide plate along a left-right direction, wherein the non-welding region is bent between the upper guide plate and the lower guide plate.

17. The method for manufacturing the test head as claimed in claim 16, wherein in Step (b), the at least one welding region is formed by welding the mutually stacked metal sheets using a resistance welding method.

18. The method for manufacturing the test head as claimed in claim 16, wherein in Step (c), two welding regions are patterned in the metal sheet such that each individual probe cut therefrom includes a welding region at both ends.

19. The method for manufacturing the test head as claimed in claim 16, wherein in Step (c), multiple probes are formed and arranged side by side by cutting, and one of the two ends of the at least one probe is connected to the metal sheets, while the other end is severed from the metal sheets; and
in Step (d), at least some of the multiple probes connected to the metal sheets are collectively inserted into the upper guide plate and the lower guide plate, after which the connections between the probes and the metal sheets are severed.

20. The method for manufacturing the test head as claimed in claim 16, wherein in Step (a), at least two base materials of a high-conductivity material are provided, the base material is defined as the high-conductivity layer, and a high-hardness layer is plated on at least one of the front and rear sides of each high-conductivity layer, thereby forming the metal sheet.
